(19) United States
(12) Patent Application Publication
(10) Pub. No.: US 2012/0037068 A1
(43) Pub. Date: Feb. 16, 2012

(54) COMPOSITE SUBSTRATES FOR DIRECT HEATING AND INCREASED TEMPERATURE UNIFORMITY

(75) Inventors: Jie Su, Santa Clara, CA (US); Donald J.K. Olgado, Palo Alto, CA (US); Michael C. Kutney, Santa Clara, CA (US)

(73) Assignee: APPLIED MATERIALS, INC., Santa Clara, CA (US)

(21) Appl. No.: 13/026,874

(22) Filed: Feb. 14, 2011

Related U.S. Application Data
(60) Provisional application No. 61/372,771, filed on Aug. 11, 2010.

(51) Int. Cl. C30B 25/02; B23Q 3/00; F27D 11/00

(52) U.S. Cl. 117/95; 219/385; 269/289 R

(57) ABSTRACT

Embodiments of the present invention generally relate to apparatus and methods for uniformly heating substrates. The apparatus include a transferable puck having at least one electrode and a dielectric coating. The transferable puck can be biased with a biasing assembly relative to a substrate, and transferred independently of the biasing assembly during a fabrication process while maintaining the bias relative to the substrate. The puck absorbs radiant heat from a heat source and uniformly conducts the heat to a substrate coupled to the puck. The puck has high emissivity and high thermal conductivity for absorbing and transferring the radiant heat to the substrate. The high thermal conductivity allows for a uniform temperature profile across the substrate, thereby increasing deposition uniformity. The method includes disposing a light-absorbing material on an optically transparent substrate, and radiating the light-absorbing material with a radiant heat source to heat the optically transparent substrate.

### CROSS-REFERENCE TO RELATED APPLICATIONS

This application claims benefit of U.S. Provisional Patent Application Ser. No. 61/372,771, filed Aug. 11, 2010, which is herein incorporated by reference.

### BACKGROUND OF THE INVENTION

1. Field of the Invention

Embodiments of the present invention generally relate to methods and apparatus for uniformly heating substrates during epitaxial growth processes.

2. Description of the Related Art

The advantage of compound semiconductors (e.g., gallium nitride or gallium arsenide) holds much promise for a wide range of applications in electronics (high frequency, high power devices and circuits) and optoelectronics (lasers, light-emitting diodes and solid state lighting). Generally, compound semiconductors are formed by heteroepitaxial growth on a substrate material. The lattice mismatch and difference in thermal expansion between the compound semiconductor and the substrate causes the substrate to deform or bow during processing. The bowing of the substrate places a portion of the substrate closer to a heating source used during the epitaxial layer formation process which causes a non-uniform temperature profile across the surface of the substrate. Thermal uniformity of the substrate is important since the epitaxial layer composition, and thus LED emission wavelength, is a strong function of the surface temperature of the substrate. Additionally, since the surface of the substrate may have a non-uniform temperature profile, the formation rate of the epitaxial layer may be non-uniform across the substrate surface. In extreme cases, the substrate can bow enough to crack or break, damaging or ruining the epitaxial layer grown thereon.

Typically, substrates are positioned on a substrate carrier during processing. The substrate carrier is designed to transfer heat to the substrates during an epitaxial growth process. The substrate carrier may be flat, or may have pockets formed therein which attempt to mimic the bowed-shape of the substrate during processing. However, due to the unrepeatability of the shape of the substrate during processing, different portions and varying amounts of surface area of the substrates will be in contact with the substrate carrier during a deposition process. Since the surface area of the substrates in contact with the substrate carrier is inconsistent, varying amounts of heat will be transferred to each substrate. The variance in thermal profiles between substrates results in differing deposited film properties and the non-uniform growth of the epitaxial films, thereby decreasing process repeatability, and ultimately, device performance. Furthermore, the non-uniform thermal profile of the substrate may induce additional bowing of the substrate, which may lead to cracking or breaking of the substrate.

Therefore, there is a need for more uniformly applying heat and for reducing the amount of bow of substrates when forming compound semiconductors.

### SUMMARY OF THE INVENTION

Embodiments of the present invention generally relate to apparatus and methods for uniformly heating substrates. The apparatus include a transferable puck having at least one electrode and a dielectric coating. The transferable puck can be biased with a biasing assembly relative to a substrate, and transferred independently of the biasing assembly during a fabrication process while maintaining the bias relative to the substrate. The puck absorbs radiant heat from a heat source and uniformly conducts the heat to a substrate coupled to the puck. The puck has high emissivity and high thermal conductivity for absorbing and transferring the radiant heat to the substrate. The high thermal conductivity allows for a uniform temperature profile across the substrate, thereby increasing deposition uniformity. The method includes disposing a light-absorbing material on an optically transparent substrate, and radiating the light-absorbing material with a radiant heat source to heat the optically transparent substrate.

In one embodiment, a transferable puck for supporting a substrate comprises at least one electrode having a dielectric coating thereon. A portion of the at least one electrode is exposed through the dielectric coating and is adapted to be contacted by a biasing assembly.

In another embodiment, a transferable puck for supporting a substrate comprises at least one electrode and a dielectric coating disposed over the at least one electrode. A portion of the at least one electrode is exposed through the dielectric coating and is adapted to be contacted by a biasing assembly. The at least one electrode is adapted to maintain a bias relative to the substrate while being transferred independent of the biasing assembly during a fabrication process.

In another embodiment, a method of forming an epitaxial film comprises disposing a light-absorbing material having an emissivity within a range from about 0.3 to about 0.95 on a first surface of an optically transparent substrate. The optically transparent substrate is positioned within a processing chamber. The optically transparent substrate is supported by a substrate support disposed in the processing chamber. Energy is then delivered to the light-absorbing material from one or more lamps. The one or more lamps are positioned to deliver energy to the light-absorbing material through an opening formed in the substrate support. An epitaxial layer is then formed on a second surface of the optically transparent substrate that is opposite to the first surface of the optically transparent substrate.

In another embodiment, a substrate used to support at least a portion of a light emitting diode or laser diode device during processing comprises an optically transparent substrate. The optically transparent substrate has a first side and a second side. The second side is on a side opposite to the first side. A light-absorbing material is disposed on the first side of the optically transparent substrate, and the second side is configured to receive one or more layers used to form a light emitting diode or laser diode device.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A and 1B are schematic illustrations of a composite substrate positioned on an annular substrate carrier.

FIGS. 2A-2F are schematic illustrations of composite substrates according to other embodiments of the invention.

FIGS. 3A and 3B are schematic illustrations of a flexible puck according to another embodiment of the invention.

FIGS. 4A-4E are schematic illustrations of a composite substrate according to another embodiment of the invention.

FIGS. 5A-5D are schematic illustrations of a substrate carrier according to embodiments of the invention.

FIGS. 6A-6C are schematic illustrations of a puck having a bonding layer thereon.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally relate to apparatus and methods for uniformly heating substrates. The apparatus include a transferable puck having at least one electrode and a dielectric coating. The transferable puck can be biased with a biasing assembly relative to a substrate, and transferred independently of the biasing assembly during a fabrication process while maintaining the bias relative to the substrate. The puck absorbs radiant heat from a heat source and uniformly conducts the heat to a substrate coupled to the puck. The puck has high emissivity and high thermal conductivity for absorbing and transferring the radiant heat to the substrate. The high thermal conductivity allows for a uniform temperature profile across the substrate, thereby increasing deposition uniformity. The method includes disposing a light-absorbing material on an optically transparent substrate, and radiating the light-absorbing material with a radiant heat source to heat the optically transparent substrate.

Due to extrinsic and intrinsic stress created in a substrate during various heating and deposition processes, a processed substrate will tend to deform into a shape (e.g., convex or concave) that has an undesirable, unrepeatable and possibly variable curvature. In general, the curvature (K) of a substrate is equal to the inverse radius (r) of the bow curve (e.g., K=1/r). The bow (B) of the substrate is equal to one-half the curvature (K) of the substrate multiplied by the radius (R) of the substrate squared (e.g., B=(K/2*R²)). Thus, the bow of the substrate is proportional to the square of the radius (R) of the substrate. The bow is typically defined as the distance from the edge of the substrate to the maximum deflection of the substrate, or, for example, in a simple concave shaped substrate it is the distance from the deflected center of the substrate to the edge of the substrate in a direction passing through the center point of the substrate and the center of the curvature.

An increase in substrate size can cause an increase in substrate bow, due to the substrate curvature (the inverse radius of the arc formed by the substrate). This effect becomes especially pronounced in substrates having a diameter of six inches or greater. The substrate bow causes non-uniform heating and non-uniform epitaxial formation during epitaxial growth processes, which further induces stress and bowing on the substrate because of the increasing non-uniformity of the epitaxial layer. For curvatures of 50 millimeters and 100 millimeters, a two inch substrate has a theoretical bow of about 16 to about 32 micrometers. A four inch substrate has a theoretical bow of about 64 to about 129 micrometers. A six inch substrate has a theoretical bow of about 145 to about 290 micrometers. An eight inch substrate has a theoretical bow of about 258 to about 516 micrometers. Thus, as substrate size increases, the amount and proportionate variation in the bow of the substrate also increases.

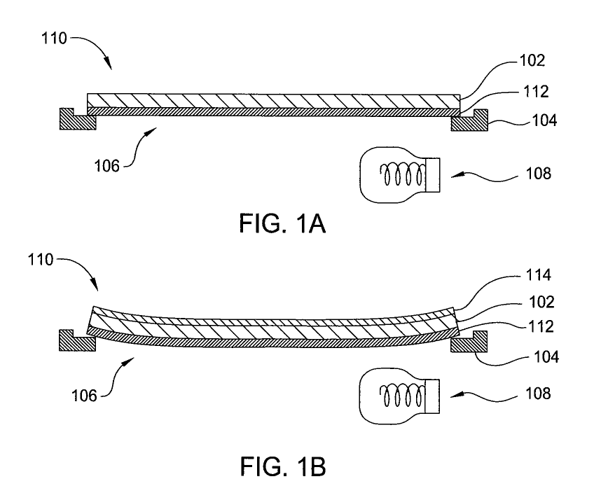

FIGS. 1A and 1B are schematic illustrations of a composite substrate positioned on an annular substrate carrier. FIG. 1A illustrates a composite substrate 110 positioned on an annular substrate carrier 104. The annular substrate carrier 104 is formed from silicon carbide and has an opening 106 disposed therethrough. The composite substrate 110 includes a substrate 102 and a thermally-conducting layer 112 disposed on a back surface of the substrate 102. In one configuration, the substrate may further comprise a plurality of surface features, such as random texture, formed geometric features (e.g., micron sized pyramids), holes or other useful surface topography, formed on the front surface of the substrate to promote the growth of an epitaxial layer that has desirable properties (e.g., reduced number of defects, improve stress). The substrate 102 is made of a material compatible for growing an epitaxial layer thereon; for example, a single crystal substrate made of sapphire or silicon. However, single crystal substrates are just one type of substrate which may benefit from embodiments disclosed herein. In one example, the substrate 102 is a sapphire substrate, which generally has an optical transmittance of at least 80% for wavelengths of light between about 0.3 and about 4.5 μm. In one example, the substrate 102 is a patterned sapphire substrate (PSS). In another example, the substrate 102 is a silicon substrate, which generally has an optical transmittance of about 50% or greater for wavelengths of light between about 1.5 and about 9 μm, such as between 3 and about 5 μm. It is contemplated that other substrates as known in the industry may also benefit from embodiments disclosed herein. For example, the substrate 102 may be gallium arsenide or silicon carbide, among others.

The thermally-conducting layer 112 is a layer or coating with high emissivity and high thermal conductivity, and is capable of absorbing heat from a radiant heat source, such as lamp 108. In one configuration, tungsten-halogen lamps are used, which emit a large portion of the optical energy (e.g., up to 85 percent) in the infrared region, and primarily in the wavelengths between about 0.2 μm and about 3.0 μm (e.g., near-infrared region). Therefore, in conventional lamp heating applications, one will note that a large portion of the emitted energy from a lamp (e.g., tungsten-halogen lamp) will not be effectively or efficiently absorbed by a bare optically transparent substrate (e.g., sapphire and/or silicon substrates), thus there is need for the various embodiments of the invention described herein.

It is desirable that the thermally-conducting layer 112 has a high affinity for absorbing all or most of the wavelengths of radiant heat provided by a radiant heating source, such as lamp 108. It is also desirable that the thermally-conducting layer 112 has a high thermal conductivity to evenly deliver absorbed radiant heat to the substrate 102. The emissivity of the thermally-conducting layer 112 may be within a range of about 0.3-0.95, such as about 0.8 to about 0.95. However, it is contemplated that materials with other emissivities may be used, as long as the emissivity is sufficient to absorb the radiant energy at the emitted wavelengths supplied by the lamp 108. The thermal conductivity of the thermally-conducting layer 112 is generally about 100 W/m·K or greater, such as about 120 W/m·K or greater, or within a range from about 200 W/m·K to about 500 W/m·K. If the thermal conductivity of the thermally-conducting layer 112 is too low, then uneven heating of the substrate 102 may occur since the heat absorbed by the thermally-conducting layer 112 will not be evenly distributed.

To further assist in the even distribution of absorbed heat, the thermally-conducting layer 112 should have a sufficient thickness to allow for lateral transfer of absorbed heat during an epitaxial growth process. Generally, the thermally-conducting layer 112 has a thickness within a range from about 0.1 micrometer to about 300 micrometers. For example, the thermally-conducting layer 112 may have a thickness of about 100 micrometers to about 200 micrometers. Depending on the type of substrate being processed and the material used for the thermally-conducting layer, the ratio of the thickness of the substrate 102 to the thermally-conducting layer may be about 1000:1 to about 3:1. For example, the ratio of the thickness of the substrate 102 to the thickness of the thermally-conducting layer 112 may be about 20:1 to about 5:1.

The thermally-conducting layer 112 is a metal-containing material. It is contemplated that the thermally-conducting layer 112 may be formed from other materials, including refractory metals, refractory metal alloys, or dielectrics. For example, the thermally-conducting layer may be formed from sintered polysilicon carbide, titanium, titanium nitride, tungsten, tungsten nitride, cobalt, boron nitride and silicon nitride. Silicon carbide generally has an emissivity within a range from about 0.83 to about 0.96 and thermal conductivity of about 120 W/m·K. The thermally-conducting layer 112 is deposited or coated on the substrate 102 by chemical vapor deposition. However, other deposition processes, such as physical vapor deposition, evaporation, or the like may also be used to form the thermally-conducting layer 112 on the substrate 102.

Preferably, the thermally-conducting layer 112 is capable of withstanding the elevated temperatures used in an epitaxial growth process without contaminating the epitaxial growth chamber, such as about 1200 degrees Celsius or less. In the embodiment of FIG. 1A, the composite substrate 110 is illustrated prior to an epitaxial growth process.

In the typical processing of substrates, heat is provided to a substrate by first heating the substrate carrier, and then conducting the heat to the substrate which is in physical contact with the substrate carrier. Substrate carriers which conduct heat to the substrate are often solid (lacking a central opening), and may be planar or have pockets formed therein. A solid substrate carrier is often used to conduct heat to the substrate because it is believed that this will allow more area to be in thermal contact between the substrate and the substrate carrier. Substrates generally are heated by thermal conduction since substrates are often optically transparent and therefore poorly absorb heat radiated from lamps. However, heating substrates by conducting heat through the substrate carrier to the substrates often results in non-uniform heating of the substrate due to the bowing of the substrate during processing. The bowed-shape of the substrate results in non-uniform thermal contact and conduction of heat to the substrate, which undesirably affects deposition uniformity. Therefore, it is desirable to more uniformly apply heat to a substrate during processing.

The composite substrate 110 need not rely upon the conduction of heat from the substrate carrier 104, since the thermally-conducting layer 112 has been applied to the substrate 102. The thermally-conducting layer 112, which is part of the composite substrate 110, is capable of absorbing heat from the lamp 108 and conducting the absorbed heat to the substrate 102 during epitaxial processing. Since the composite substrate 110 is not primarily heated during processing by heat conducted through the substrate carrier 104, an opening 106 can be formed in the substrate carrier 104. The opening 106 provides a path for heat to directly irradiate the composite substrate 110, and also reduces the surface area of the composite substrate in contact with the substrate carrier 104 during processing. Therefore, even if the composite substrate 110 bows during processing, uneven thermal conduction of heat from the substrate carrier 104 to the composite substrate 110 is minimized, since less surface area of the composite substrate 110 is in contact with the substrate carrier 104.

FIG. 1B illustrates the composite substrate 110 positioned on the annular substrate carrier 104 while receiving light from the lamp 108 during an epitaxial growth process. The lamp 108 is positioned beneath the composite substrate 110, and may be located outside of a process chamber or disposed within a process chamber wall. The radiant heat emitted by the lamp 108 is absorbed by the thermally-conducting layer 112 during the epitaxial growth process, and transferred to the substrate 102 via conduction. Thus, composite substrate 110 is able to directly absorb radiant heat using thermally-conducting layer 112, which is not optically transparent. The high thermal conductivity of the thermally-conducting layer 112 allows for a uniform temperature profile within the thermally-conducting layer 112. Consequently, a uniform temperature profile is created within the substrate 102. Furthermore, unlike the substrates and solid substrate carrier combinations used in typical substrate processes, a central portion of the composite substrate 110 does not contact the substrate carrier 104 due to the opening 106 formed therein. Thus, non-uniform conduction of heat to the substrate 102 is reduced.

The thermally-conducting layer 112 is not only beneficial for absorbing radiant energy, but also serves to increase the rigidity of the substrate 102 due to increased thickness imparted by the thermally-conducting layer 112. Thus, the potential for the substrate 102 to crack or break due to bowing is reduced. Since extra support is provided by the thermally-conducting layer 112, a thinner and therefore cheaper substrate 102 may be used. For example, a substrate may require a thickness of 1300 micrometers for sufficient rigidity when performing epitaxial growth processes in the absence of the thermally-conducting layer 112. However, when the thermally-conducting layer 112 is applied to the substrate 102, the thickness of the substrate 102 can be reduced to about 900 micrometers. Generally, the material from which the substrate 102 is formed is significantly more expensive than the material from which the thermally-conducting layer 112 is formed. Therefore, the reduction in the thickness of the substrate 102 provides a cost savings when performing epitaxial growth processes.

Subsequent to an epitaxial growth process, the composite substrate 110 can optionally be removed from the epitaxial layer 114 by chemical or mechanical means. For example, the composite substrate 110 can be removed by grinding, polishing or etching. Alternatively, the composite substrate 110 may remain coupled to the epitaxial layer 114, or only the thermally-conducting layer 112 may be removed while the substrate 102 remains coupled to the epitaxial layer 114.

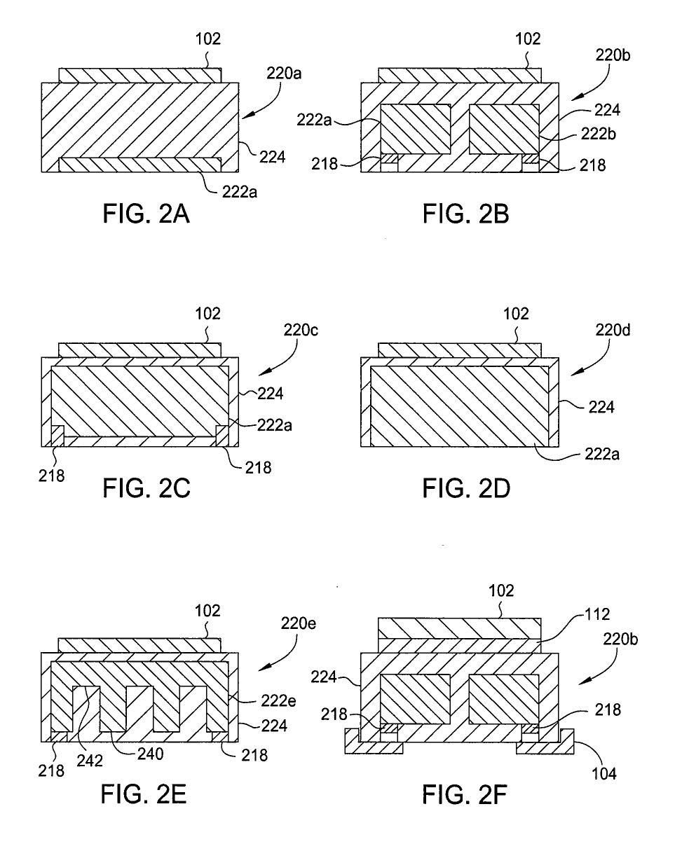

FIGS. 2A-2F are schematic views of composite substrates according to other embodiments of the invention. The composite substrates of FIGS. 2A-2F include a substrate 102 coupled to one of pucks 220a-220e. The pucks generally include a dielectric layer 224 and one or more electrodes 222a-222b. The pucks 220a-220e serve a similar purpose to the thermally-conducting layer 112, as discussed above. However, the pucks 220a-220e can be attached and detached from the substrate, and thus are reusable in subsequent epitaxial growth processes. The pucks 220a-220e can be temporarily attached to the substrate 102 on the side opposite of which epitaxial growth is to occur. After the epitaxial growth process, the pucks 220a-220e may be removed and reused on a different substrate in another epitaxial growth process. The pucks 220a-220e are adapted to be positioned on a substrate support or substrate carrier, such as a quartz support located within a processing chamber.

The pucks 220a-220e are sufficiently thin to enable transfer amongst a plurality of different process chambers or locations during a fabrication process. During the transfer, the pucks 220a-220e can remain coupled to the substrate 102, for example, by electrostatic forces, since the pucks 220a-220e are able to maintain an electrical bias relative to the substrate 102 until the bias is dissipated. Because of the size of the pucks 220a-220e, the pucks 220a-220e can be coupled to a substrate 102 outside of an epitaxial growth chamber, and then transferred into the epitaxial growth chamber for processing, thus increasing ease of handling, or replacement when necessary. It is not necessary for the pucks to be fixed or secured to a pedestal within the epitaxial process chamber during an epitaxial growth process. Furthermore, due to the size of the pucks 220a-220e, a plurality of pucks 220a-220e can be supported and transferred on a substrate carrier 104 simultaneously. It is desirable that the pucks 220a-220e are sufficiently thin in order to be supported by the substrate carrier 104, which is generally formed from silicon carbide, and has a thickness within a range of about 2.0 millimeters to about 2.7 millimeters.

The electrodes 222a-222b of pucks 220a-220e are formed from a conductive material, such as tungsten. It is contemplated that other conductive materials, such as titanium, molybdenum, tantalum, or cobalt may also be used. It is desirable that the material of the electrodes 222a-222b has a thermal conductivity of at least about 120 W/m·K and be non-reactive with process gases used to grow an epitaxial layer. Additionally, it is desirable that the electrodes 222a-222b can withstand the process temperatures reached during an epitaxial growth process; for example, up to about 1200 degrees Celsius. The dielectric coating 224 is formed from a ceramic such as alumina. However, it is contemplated that the dielectric coating 224 may be formed from other materials as well. For example, the dielectric coating may be silicon nitride, aluminum nitride, boron nitride, or pyrolytic boron nitride. Desirably, the dielectric coating has an emissivity greater than about 0.3, such as about 0.8-0.95. Additionally or alternatively, it is contemplated that the surface of the dielectric coating can be altered to increase the emissivity of the dielectric coating.

FIG. 2A illustrates a puck 220a coupled to a substrate 102. The puck 220a includes an electrode 222a and a dielectric coating 224 disposed over the electrode 222a. The electrode 222a is partially exposed on the bottom side of the puck 220a to allow an electrical bias to be applied to the electrode 222a. The thickness of electrode 222a is within a range from about 100 micrometers to about 1 millimeter or greater, such as about 500 micrometers to about 1 millimeter. The thickness of the electrode 222a accounts for about 5 percent to about 30 percent of the overall thickness of the puck 220a. The dielectric coating 224 is a ceramic which is generally less flexible than the electrode 222a. Thus, since a greater amount of the puck 220a is formed from the dielectric coating 224 as compared the electrode 222a, the puck 220a will be relatively rigid. The relative rigidity of the puck 220a reduces the bowing of the substrate 102 during processing. Since the substrate is chucked to the puck 220a during processing, the substrate 102 is forced to remain substantially planar as dictated by the puck 220a.

FIG. 2B illustrates a puck 220b coupled to a substrate 102. The puck 220b has two electrodes 222a, 222b covered with a dielectric coating 224. The two electrodes are almost completely covered with the dielectric coating 224 except for two exposed electrical contacts 218. The two electrical contacts allow the electrodes 222a, 222b to be contacted with a power source and biased relative to one another, thereby chucking substrate 102 to the puck 220b. By covering substantially all of the electrodes 222a, 222b with the dielectric coating 224, the potential for the material of the electrodes 222a, 222b to react with a processing gas during an epitaxial growth process is reduced. Thus, a material which would normally be reactive with the processing gas may be used for the electrodes 222a, 222b. Additionally, the dielectric coating 224 is generally less reflective (higher emissivity) than the material from which the electrodes 222a, 222b are formed. Therefore, the puck 220b more efficiently absorbs radiant energy compared to a puck having an exposed electrode on the underside. The electrical contacts 218 are formed from the same material as the electrodes 222a, 222b; however, it is contemplated that other conductive materials may be used to form the electrical contacts 218.

The electrodes 222a, 222b are shaped as half-circles and have a thickness of about 1 millimeter; however, other electrode shapes are contemplated. The electrodes 222a, 222b account for about 40 percent to about 60 percent of the thickness of the puck 220b. Since the dielectric coating 224 of the puck 220b accounts for less of the thickness of the puck 220b as compared to puck 220a, puck 220b is more flexible than puck 220a. However, it is contemplated that relative thicknesses of electrodes 222a, 222b, and dielectric coating 224 can be adjusted to obtain the desired flexibility of puck 220b. Additionally, the material from which electrodes 222a, 222b are formed, such as a metal, generally has a higher thermal conductivity than the material from which the dielectric coating 224 is formed (e.g., a ceramic). Therefore, pucks which are composed of a greater amount of electrode material generally have a more uniform temperature distribution due to the increased thermal conductivity of the electrode material compared to the dielectric coating material.

FIG. 2C illustrates a puck 220c coupled to a substrate 102. The puck 220c includes an electrode 222a and a dielectric coating 224. The dielectric coating 224 completely surrounds the electrode 222a except for two electrical contacts 218 which are used to apply an electrical bias to the electrode 222a. The thickness of the electrode 222a is about 500 micrometers. The dielectric coating 224 is preferably alumina deposited by physical vapor deposition to a thickness within a range from about 10 nanometers to about 1000 nanometers. For example, the dielectric coating 224 may be physical vapor deposited to a thickness within a range from about 300 nanometers to about 500 nanometers. Alternatively, the dielectric coating may be a plasma-sprayed coating deposited to a thickness of about 100 micrometers or greater.

The composition of the puck 220c includes a greater amount of electrode 222a as compared to the puck 220a. Thus, puck 220c is slightly more flexible than puck 220a, since the electrode 222a is generally more flexible than the dielectric coating 224. Additionally, the material from which the electrode 222a is formed generally has a higher thermal conductivity than the material from which the dielectric coating 224 is formed. Therefore, pucks which have a relatively larger electrode 222a, such as puck 220c, will generally have a more uniform temperature distribution during processing. The higher thermal conductivity and uniform temperature of puck 220c results in more uniform heating of the substrate 102 coupled thereto, thus resulting in more uniform epitaxial growth thereon.

FIG. 2D illustrates a puck 220d coupled to a substrate 102. The puck 220d includes an electrode 222a and a dielectric coating 224. The bottom portion of the electrode 222a is exposed through the dielectric coating 224 so that the electrode 222a may be contacted with a power source to bias the electrode 222a and to chuck the substrate 102 to the puck 220d. Similar to puck 220c, the electrode 222a of puck 220d is relatively larger than the dielectric coating 224. Thus, the puck 220d is relatively flexible (allowing substrate 102 to bow slightly during processing) and has increased thermal conductivity.

FIG. 2E illustrates a puck 220e coupled to a substrate 102. The puck 220e includes an electrode 222e and a dielectric coating 224. The electrode 222e has a comb-like cross section. The electrode 222e has a circular-shaped disk 242 having perpendicular extensions 240 extending therefrom. The extensions 240 occupy space which would otherwise be occupied by the less-flexible dielectric coating 224, thereby increasing flexibility. Additionally, the disk 242, having a thickness less than the extensions 240, provide points of increased flexibility between the extensions 240 to allow the puck 220e to have a greater range of flexible motion. Although the electrode 222e is shown as having a comb-like shape, other shapes which may allow for increased flexibility are contemplated. For example, it is contemplated that the electrode 222e may also have a waffle shape, a grid shape, or may be formed from flexible wiring.

The dielectric coating 224 surrounds the electrode 222e except for exposed portions where electrical contacts 218 may be positioned. The electrical contacts 218 allow a power source to be electrically coupled to the electrode 222e to bias the electrode 222e and to chuck the substrate 102 to the puck 220e. The electrode 222e is formed from the same materials as the electrodes 222a, 222b; however, the electrode 222e is shaped to allow the puck 220e to have a greater range of flexibility. Thus, during processing, as the substrate 102 bows due to epitaxial growth thereon, the puck 220e will also bow with the substrate 102. Therefore, since the puck 220e can bow with the substrate 102, resistive stresses which would otherwise be imparted to the substrate 102 by a non-flexible puck are reduced. The reduction in resistive stress can help to reduce the damage to the substrate 102 during processing.

FIG. 2F illustrates a composite substrate having both a thermally-conducting layer 112 and a puck 220b coupled to a substrate 102. FIG. 2F illustrates the puck 220b coupled to a substrate 102 and positioned on a substrate carrier 104. The substrate 102 has a thermally-conducting layer 112 disposed on a lower surface of the substrate 102 and positioned between the substrate 102 and the puck 220b. The thermally-conducting layer 112 is titanium; however, other materials are contemplated for the thermally-conducting layer 112, such as titanium nitride, tungsten, or cobalt. It is desirable that the thermally-conducting layer is at least partially electrically conductive, thereby reducing the voltage required to chuck the puck 220b to the substrate 102 and decreasing the potential for unintentional dechucking at elevated processing temperatures.

The electrical contacts 218 of the puck 220b are covered by the substrate carrier 104, thus, the potential for the contacts 218 reacting with deposition processes gases is reduced. Alternatively, it is contemplated that the electrical contacts 218 may remain exposed while the puck 220b is positioned on the substrate carrier 104. When the electrical contacts 218 are exposed, the substrate 102 can be chucked and dechucked while the puck 220b remains positioned on the substrate carrier 104.

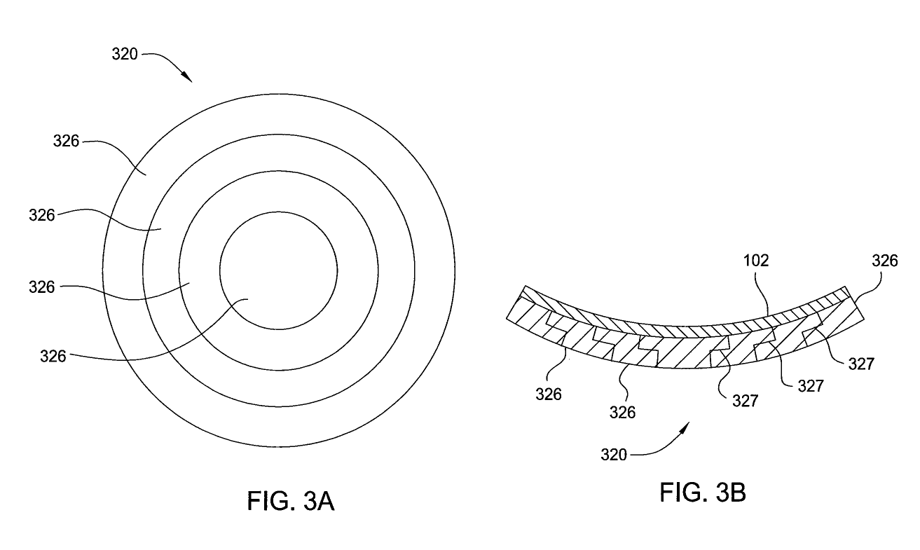

FIGS. 3A and 3B are schematic illustrations of pucks according to another embodiment of the invention. In the embodiment shown in FIG. 3A, a puck 320 is formed from multiple concentric rings 326 which are movable relative to one another. The concentric rings 326 may be coupled together by tabs, springs, interlocking parts, or any other satisfactory method. The puck 320 may be glued to the lower surface of the substrate 102; however, it is contemplated that the puck 320 may be coupled to the substrate 102 in any suitable manner. For example, any of the concentric rings 326 may include electrodes having a dielectric coating formed thereon. Alternatively, any of the concentric rings 326 may contain a matrix of conductive particles allowing the puck 320 to be electrostatically coupled to a substrate.

FIG. 3B illustrates the concentric rings 326 of the puck 320 formed into a concave shape and coupled to the substrate 102. The concentric rings 326 include tabs 327 which are bonded together with a flexible adhesive. Since the concentric rings 326 are sufficiently flexible, the concentric rings 326 are free to assume the shape of an object coupled thereto. For example, if the substrate 102 has a tendency to form a curved shape during processing, the puck 320 will also form a curved shape as induced by the substrate 102. Thus, the shape of the puck 320 is dictated by the shape assumed by the substrate 102 during processing. The flexibility of the puck 320 reduces the amount of resistive stress which would otherwise be applied by a more rigid material or puck attempting to hold substrate 102 in a planar shape.

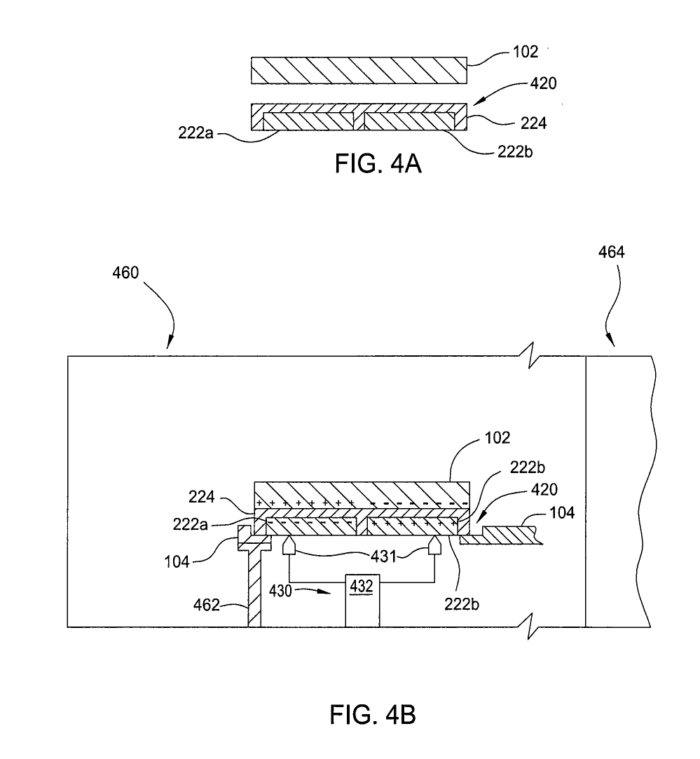

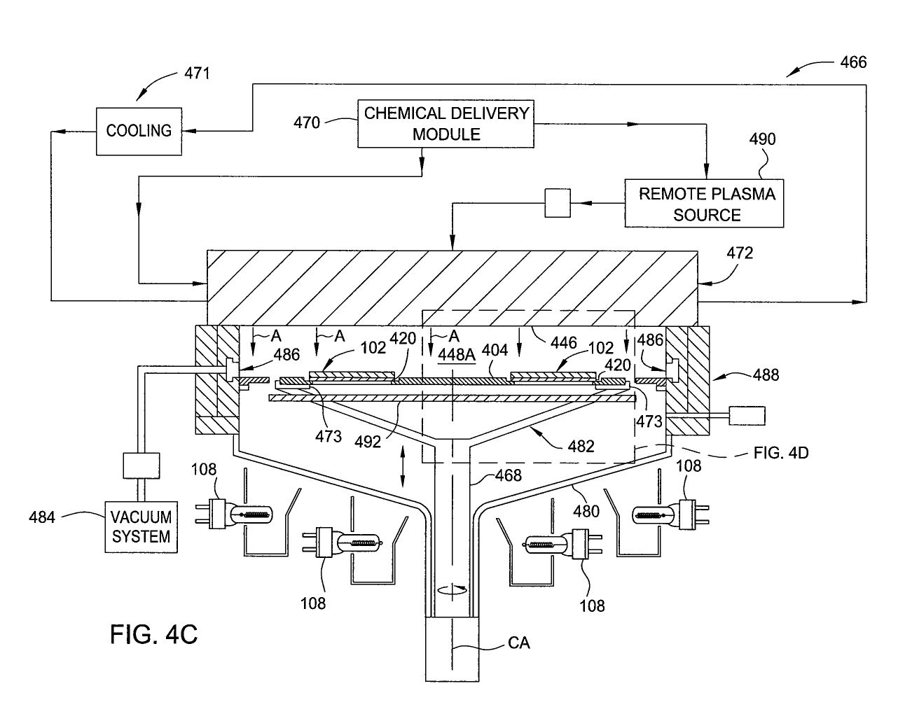

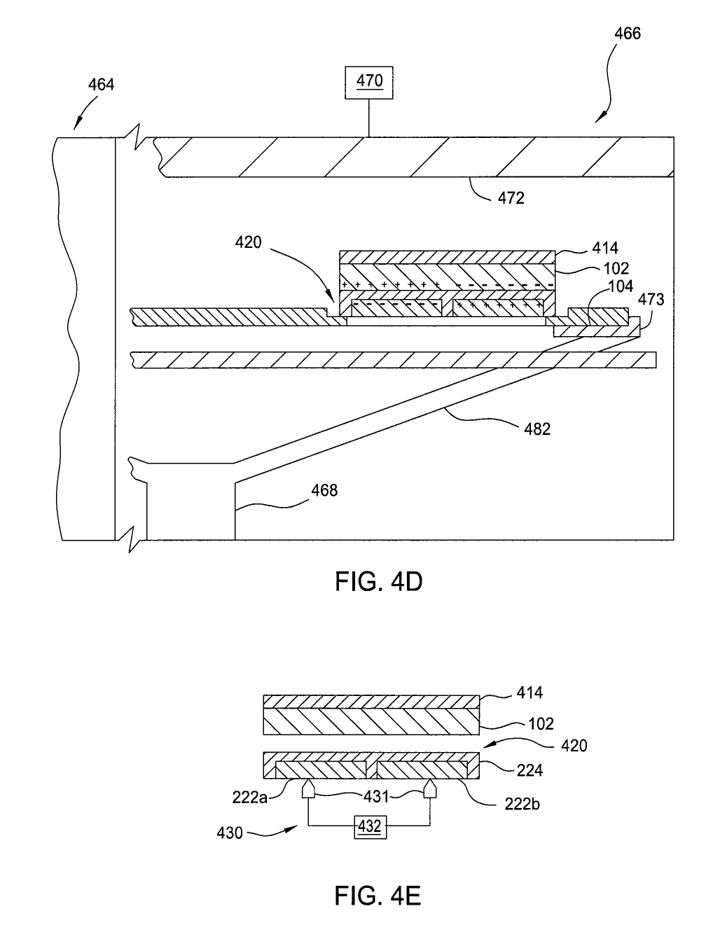

FIGS. 4A-4E are schematic illustrations of a composite substrate according to another embodiment of the invention. FIG. 4A illustrates a substrate 102 that may be used for growing an epitaxial layer thereon and a puck 420. The puck 420 is similar to puck 220b; however, a relatively larger surface of the electrodes 222a and 222b are exposed through the dielectric coating 224. Thus, the electrodes 222a and 222b can be contacted directly by a power source.

The electrodes 222a, 222b can be separately biased to electrostatically couple the substrate 102 to a surface of the puck 420. The one or more electrodes 222a, 222b are covered with a dielectric coating 224. The dielectric coating 224 allows the puck 420 to be electrostatically chucked to the substrate 102 via the one more electrodes 222a, 222b. The emissivity and thermal conductivity of the dielectric coating 224 are preferably sufficient to absorb a large percentage of the transmitted heat from a radiant heat source and readily transmit the adsorbed heat to the substrate 102 during an epitaxial growth processes. The dielectric coating should also be corrosion-resistant to plasma and plasma processes, and be able to withstand process temperatures of about 1200 degrees Celsius or less.

FIG. 4B illustrates the puck 420 electrostatically coupled to the substrate 102. The backside of the substrate 102 is placed in contact with the upper surface of the puck 420. The puck 420 is positioned on substrate carrier 104, and positioned in a processing chamber 460 on a support 462. A bias is applied across the electrodes 222a and 222b by a biasing assembly 430. During the biasing process, charges migrate to the interface between the substrate 102 and the dielectric coating 224 disposed over the one or more electrodes 222a, 222b. The bias is effected by the biasing assembly 430, which includes power supply 432 and contact pins 431. In one configuration, the contact pins 431 are titanium, but it is contemplated that the contact pins 431 may be any conductive material sufficient to reliably electrically couple the one or more electrodes 222a, 222b to the power supply 432.

The power supply 432 is a direct current power supply adapted to provide a bias of about 1000 volts. The charge provided by the power supply 432 is sufficient to chuck the substrate 102 to the puck 420. The voltage need not be continuously applied, since the charge at the interface will remain until it is dissipated. This allows for the coupled substrate 102 and the puck 420 to be transferred independent of the biasing assembly 430 during processing. Generally, the puck 420 and the substrate 102 are electrostatically coupled together outside of the epitaxial process chamber 466 and then transferred via a robot into the epitaxial process chamber 466, since the power supply need not remain coupled to the electrodes 222a, 222b. Thus, puck 420 is adapted to be transferred during a fabrication process (e.g., a process for epitaxial growth on substrate 102) while remaining chucked to the substrate, due to the separated charge remaining in the substrate 102 and puck 420. In FIG. 4B, the puck 420 and the substrate 102 are chucked in the processing chamber 460; however, it is contemplated that the puck 420 and the substrate 102 may be chucked in other locations, including a transfer chamber 464 or a loadlock chamber. It is also contemplated that the puck 420 and the substrate 102 may also be coupled together in the same chamber as is used for epitaxial deposition.

FIG. 4C illustrates an epitaxial process chamber 466 that may be used to form an epitaxial layer 414, such as gallium nitride, on a substrate 102. The epitaxial process chamber 466 includes a lower dome 480, a showerhead 472, and a quartz support shaft 468 disposed therebetween. The support shaft 468 is rotatable about an axis “CA”, and includes support legs 482 extending upwardly therefrom and coupling to an annular support ring 473. The support shaft 468, the support legs 482, and the annular support ring 473 are formed from quartz. The annular support ring 473 has a central opening which allows light radiated from lamps 108 to be absorbed by the pucks 420. The pucks 420 are disposed on a substrate carrier 404, which is similar to substrate carrier 104, except substrate carrier 404 is adapted to carry a plurality of substrates 102. The substrate carrier 404 is disposed upon the annular support ring 473 during an epitaxial growth process. It should be noted that while FIG. 4C illustrates a processing chamber configuration that has a plurality of substrates 102 and pucks 420 disposed on a substrate carrier 404, this configuration is not intended to be limiting as to the scope of the invention described herein, since other embodiments of the invention described herein could also be used.

In one configuration, the showerhead 472 includes multiple gas delivery channels that are each configured to uniformly deliver one or more processing gases to the substrates disposed in the processing volume 448A. The multiple gas delivery channels are coupled with the chemical delivery module 470 for delivering one or more precursor gases normal, or perpendicular, to a surface of the substrates 102 (e.g., reference label “A”) that is adjacent to the processing volume 448A. A temperature control channel may be formed in the showerhead 472 and coupled with a heat exchanging system 471 for flowing a heat exchanging fluid to the showerhead 472 to help regulate the temperature of the showerhead 472. In one example, it is desirable to regulate the temperature of the surface 446 of the showerhead and surfaces exposed to the processing volume to temperatures less than about 200° C. at substrate processing temperatures between about 800° C. and about 1300° C. During processing, a first precursor or a first process gas mixture may be delivered to the processing volume 448A and substrate surface via the multiple gas delivery channels formed in the showerhead 472 and coupled with the chemical delivery module 470. A remote plasma source 490 is adapted to deliver gas ions or gas radicals to the processing volume 448A via a conduit formed in the showerhead 472. It should be noted that the process gas mixtures or precursors may comprise one or more precursor gases or process gases as well as carrier gases and dopant gases which may be mixed with the precursor gases. Exemplary showerheads that may be adapted to practice embodiments described herein are described in U.S. patent application Ser. No. 12/870,465 [Atty. Dkt. No. APPM 12242.02 US], filed Sep. 29, 2010, which is herein incorporated by reference in its entirety.

A catch pan 492 is disposed beneath the substrate carrier 404. The catch pan 492 is formed from quartz or another optically transparent material to allow light to pass therethrough to permit heating of the substrates 102, and in some cases the pucks 420 as shown. The catch pan 492 is positioned to catch particulate matter which may fall through openings disposed within the substrate carrier 404, or particulates which may fall over the edge of the substrate carrier 404. Thus, the catch pan, which is a circular-shaped piece of quartz or sapphire (which may include slots to accommodate support legs 482), has a diameter that is about 5 percent to about 10 percent greater than that of the substrate carrier 404. Particulate matter (such as material which flakes off of the showerhead 472, the pucks 420, or the substrate carrier 404), which is generated during deposition processes, would fall onto the lower dome 480 in the absence of the catch pan 492. Not only is it difficult and time consuming to remove the material from the lower dome 480 (which may require disassembly of the chamber 466), but particulate matter present on the lower dome 480 also affects the amount of energy delivered from the lamps 108 to the pucks 420. The particulate matter which is present on the lower dome 480 may block some of the radiant heat emitted by the lamps 108, causing non-uniform heating of the pucks 420 and substrates 102. The non-uniform heating negatively affects the quality of the epitaxially-grown films, as discussed above.

The catch pan 492 is coupled to the support legs 482 and is located beneath the substrate carrier 404. The catch pan 492 is positioned to catch particulate matter or debris which is generated during processing due to undesired deposition and/or flaking caused by rotation of chamber components. Between deposition processes, the catch pan 492 may be removed, for example by a robot, and then cleaned and replaced. Thus, cleaning downtown is greatly reduced through utilization of the catch pan 492.

It is contemplated that the catch pan 492 may be disposed upon and supported by the annular support ring 473. The substrate carrier 404 may then be disposed upon the upper surface of the catch pan 492. In such an arrangement, the catch pan 492 may also include at least three protrusions on the upper surface thereof to position the substrate carrier 404 in a spaced apart relation from most of the catch pan 492. The protrusions generally have a height of about 0.5 millimeters to about 5 millimeters, and function to minimize the contact, and thereby thermal conduction, between the catch pan 492 and the substrate carrier 404. The reduced thermal conduction from the catch pan 492 to the substrate carrier 404 promotes uniform heating of the substrate 102 during processing. When the substrate carrier 404 is supported by the catch pan 492, both the catch pan 492 and the substrate carrier supported thereon may be removed from the chamber simultaneously by a robot. Removal of the catch pan 492 and the substrate carrier 404 simultaneously further decreases chamber down time, as well as provides additional support to the substrate carrier 404 during transportation.

During an epitaxial growth process within the epitaxial process chamber 466, a process gas is provided from a chemical delivery module 470 through the showerhead 472 into the epitaxial process chamber 466 to contact the substrates 102. The process gas may optionally be ionized in the remote plasma source 490 prior to passing through the showerhead 472. The process gas is removed from the epitaxial process chamber 466 by a vacuum system 484 via an exhaust channel 486 within the chamber wall 488. As noted above, during processing, the pucks 420 remain electrostatically chucked to the substrates 102, and need not have a power supply 432 coupled thereto. The pucks are adapted to be transferred through the transfer chamber 464 and into the epitaxial process chamber 466 while remaining electrostatically chucked to the substrates 102.

FIG. 4D is a close up view of the section of FIG. 4C denoted FIG. 4D. As shown in FIG. 4D, the puck 420 and the substrate 102 have a substantially planar shape. The planar shape of the puck 420 and the substrate 102 is accomplished by using a rigid material to form the one or more electrodes 222a, 222b and/or the dielectric coating 224. Alternatively, it is contemplated that rigidity can be maintained by using a sufficient amount of material to form the puck 420. Due to the planar shape and mechanical properties of the puck 420, the substrate 102 will maintain a planar shape when the substrate 102 is heated during the epitaxial layer 414 formation process. The rigid nature of the puck 420 will prevent the substrate 102 from bowing, thereby minimizing the allowable bow of the substrate 102.

FIG. 4E illustrates the substrate 102 subsequent to an epitaxial growth process. After an epitaxial layer 414 is formed on the substrate 102, the puck 420 is transferred out of the epitaxial process chamber 466 via a robot. The puck 420 is then unchucked from the substrate 102 by dissipating the charge maintained by electrodes 222a, 222b. The puck 420 is generally unchucked from the substrate 102 in the same location as the chucking occurred prior to the epitaxial growth process. The bias maintained by electrodes 222a, 222b is dissipated by electrically coupling the biasing assembly 430 to the electrodes 222a, 222b. The substrate 102 and epitaxial layer 414 can then be further processed, while puck 420 can be coupled to another substrate upon which an epitaxial layer is to be grown.

Although FIGS. 4A-4E are described with reference to the puck 420, it is contemplated that any puck, including pucks 220a-220e, may be coupled to the substrate 102. For example, the puck 220a, which has a single electrode, can be coupled to the substrate 102. To couple the puck 220a to the substrate 102, a reference electrode is disposed on a side of the substrate 102 opposite to the electrode 222a to chuck the substrate 102 to the puck 220a. In the single electrode configuration, the reference electrode can remain with the biasing assembly components (e.g., power supply and leads) and need not be transferred with the substrate 102. Alternatively, a plasma may be used to chuck the substrate 102 to the puck 220a inside of the epitaxial deposition process chamber.

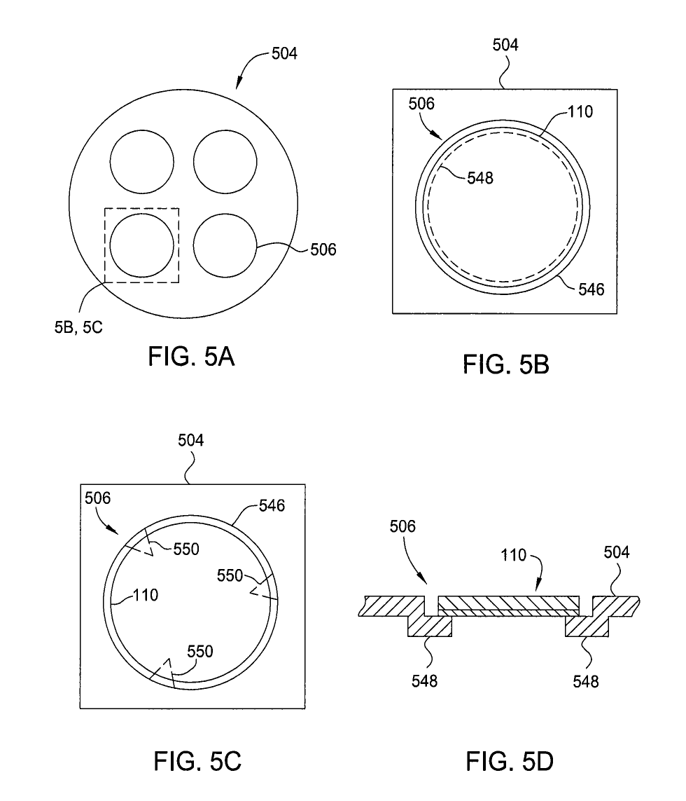

FIGS. 5A-5D are schematic illustrations of substrate carriers according to embodiments of the invention. FIG. 5A illustrates a substrate carrier 504 having openings 506 therethrough over which a composite substrate is to be positioned during processing. The substrate carrier 504 shown in FIG. 5A is similar to the substrate carrier 104. The substrate carrier 504 has four openings 506 disposed therethrough over which substrates may be positioned. Although the substrate carrier 504 is adapted to support four substrates, it is contemplated that the substrate carrier 504 may be adapted to support more or less substrates, depending on the substrate diameter and the desired throughput.

The substrate carriers 104 (as shown in FIGS. 1) and 504 are formed from silicon carbide, however, it is contemplated that substrate carriers 104 and 504 may be formed from other materials as well. For example, the substrate carriers 104 and 504 may be formed from silicon nitride or boron nitride. Alternatively, the substrate carriers 104 and 504 could be formed from a plurality of materials, including graphite coated with silicon carbide. Furthermore, the substrate carriers 104 and 504 could be formed from a metal coated with a dielectric material. In such an embodiment, the substrate carriers 104 and 504 are generally formed from metal, and all surfaces are coated with the dielectric material. It is also contemplated that only the lower light-receiving surface may be coated with a high emissivity dielectric material, including boron nitride, silicon nitride, silicon carbide, or alumina. When the dielectric material is coated only on the lower surface of the substrate carriers 104 and 504, the upper metal surface of the substrate carriers 104 and 504 may be polished to reduce heat transmittance from the upper portion of a processing chamber, such as light reflected from a showerhead. Furthermore, it is contemplated that the lower light-receiving surface may not be coated with a high emissivity dielectric material, and rather, the surface may be altered to increase the emissivity of the substrate carrier.

Suitable metals for forming the substrate carrier 504 include tungsten, titanium, titanium nitride, and other metals which are stable above epitaxial growth processing temperatures. Suitable dielectric materials include yttrium or alumina. It is desirable that the metal and the dielectric material have similar coefficients of thermal expansion to reduce the potential for delamination caused by repeated heating and cooling during processing. Generally, forming the substrate carrier 504 from a metal having a dielectric coating is cheaper and faster than forming the substrate carrier 504 from silicon carbide.

FIG. 5B illustrates an enlarged view of the openings 506 of the substrate carrier 504 according to one embodiment of the invention. A composite substrate 110 is positioned within the opening 506. The opening 506 has a vertical edge 546 perpendicular to the upper surface of the substrate carrier 504. The composite substrate 110 is positioned on a lip 548 which has a smaller diameter than the composite substrate 110. The upper surface of the lip 548 is parallel to and disposed below the upper surface of the substrate carrier 504. Desirably, there are substantially no gaps between the lip 548 and the composite substrate 110 when the substrate 110 is positioned on the lip 548 to allow radiant energy to pass therebetween. Thus, when light is irradiated from beneath the substrate carrier 504, the light is absorbed by the composite substrate 110 or the substrate carrier 504 and does not undesirably heat components within the processing chamber. It is undesirable to heat chamber components during processing because the heated chamber components may radiate heat to the composite substrate 110 thereby inducing thermal non-uniformity during epitaxial growth on the composite substrate 110.

FIG. 5C illustrates an enlarged view of the opening 506 of the substrate carrier 504 according to another embodiment of the invention. A composite substrate 110 is positioned within the opening 506. The opening 506 has a vertical edge 546 perpendicular to the upper surface of the substrate carrier 504. The composite substrate 110 is positioned on three triangular tabs 550 extending towards the center of the opening 506. It is contemplated that three or more tabs 550 may be used and that the tabs 550 may also have other shapes. The tabs 550 are generally formed form the same material as the substrate carrier 504. Since there is less physical contact between the composite substrate 110 and the tabs 550 (as compared to the composite substrate 110 and the lip 548 as shown in FIG. 5B), less heat is conducted from the substrate carrier 504 to the composite substrate 110. Therefore, since less heat is conducted form the substrate carrier 504 to the edge of the composite substrate 110, a more uniform temperature profile across the composite substrate 110 is maintained.

FIG. 5D is a sectional view of the substrate carrier 504 illustrated in FIG. 5B. FIG. 5D illustrates a composite substrate 110 positioned on the lip 548 within the opening 506 of the substrate carrier 504. The composite substrate 110 is laterally supported by the vertical surfaces of the lip 548. Sufficient space is provided between the vertical surface of the lip 548 and the composite substrate 110 to allow for thermal expansion of the composite substrate 110 during processing.

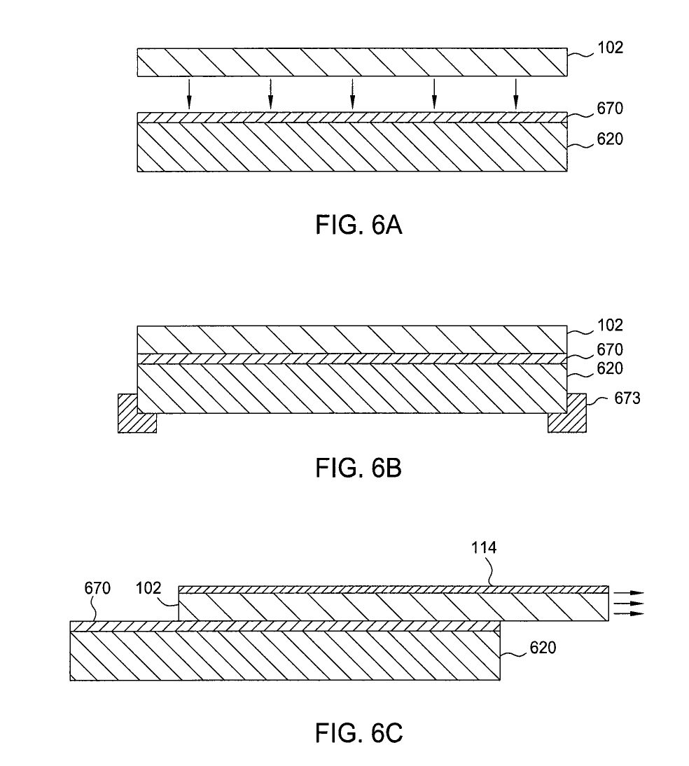

Although the above embodiments are described with reference to electrostatically chucking a substrate to a puck, the following description is directed to a substrate which is coupled to a puck via a bonding layer. FIGS. 6A-6C schematically illustrate a puck 620 having a bonding layer 670 thereon. The puck 620 is formed from silicon carbide; however, the puck 620 may also be formed from graphite coated with silicon carbide or other useful material(s). The puck 620 has a thickness within a range from about 2 millimeters to about 3 millimeters, and a diameter about equal to that of the substrate 102. For example, the puck 620 may have a diameter of about 200 millimeters to about 300 millimeters, or greater.

The bonding layer 670 is a low melting point material such as gallium; however, other materials having low melting points are also contemplated. For example, the bonding layer may be indium, non-stoichiometric combinations of gallium nitride or indium gallium nitride, or low melting point ceramics, dielectrics, or metals which will not introduce contaminants into the subsequently formed epitaxial layer(s). In one example, the bonding layer comprises one or more materials or elements found in the subsequently deposited device layers that are formed on an opposing surface of the substrate 102, so as not to dope or contaminate these subsequently formed layers during their formation or in later thermal processing steps. In one example, the bonding layer 670 has a melting point less than about 130 degrees Celsius. It is desirable that the bonding layer 670 have a sufficiently high thermal conductivity to transfer radiant energy absorbed by the puck 620 to the substrate 102 when the substrate 102 is in contact with the bonding layer 670 during processing. It is also desirable that the bonding layer 670 have a melting point that is lower than the melting point or decomposition temperature of the device layers (e.g., gallium nitride, indium gallium nitride) deposited on the substrate 102. A low melting point bonding layer 670 can allow the puck 620 and substrate 102 to be easily separated from each other after processing, thereby minimizing any thermal budget issues that may arise due to the application of the additional amount of heat required to separate these parts. Further, although the bonding layer 670 is shown as having vertical edges near the perimeter of the puck 620, it is to be understood that the bonding layer 670 will likely not have vertical edges due to the surface tension of the bonding layer 670 when in a liquid state. The edge shape of the bonding layer 670 will depend upon the contact angle of the bonding layer 670 with the substrate 102 and the puck 620. However, to assist in explanation of the embodiment, the bonding layer 670 is shown as having vertical edges.

The bonding layer 670 generally has a thickness within a range from about 2 nanometers to about 10 nanometers. The bonding layer 670 may be deposited on the puck 620 in the same chamber in which epitaxial formation is to occur. This is especially convenient in applications where the bonding layer 670 and the epitaxial layer to be formed on the substrate 102 both include the same material, for example, gallium. In such an application, the same precursor material may be used in the formation of both the epitaxial layer and bonding layer 670. When the bonding layer 670 contains gallium, relatively pure metallic gallium can be deposited on the surface of the puck 620 via a thermal process in a hydrogen containing atmosphere. Metallic gallium has a melting point of about 30 degrees Celsius. A gallium layer with a higher melting point can be deposited by incorporating small amounts of nitrogen into the bonding layer 670 through the addition of small amounts of ammonia gas in the processing atmosphere. In addition to in situ depositions, it is also contemplated that the bonding layer 670 may be deposited on the puck 620 in a chamber other than the one in which epitaxial formation is to occur. For example, the bonding layer 670 may be formed from a metal having a low melting point which is deposited by a physical vapor deposition process.

After formation of the bonding layer 670 on the puck 620, a substrate 102 is positioned on top of the bonding layer 670 and is coupled to the puck 620 by the surface tension of the bonding layer 670 while the bonding layer 670 is in a liquid state. It is to be noted that the bonding layer 670 is generally in a liquid state during an epitaxial growth process, which may occur at temperatures within a range from about 700 degrees Celsius to about 1200 degrees Celsius. In configurations where the bonding layer is formed in the epitaxial growth chamber (e.g., in situ), the substrate 102 may be transferred into the epitaxial growth chamber and positioned on a surface of a puck 620 after the bonding layer 670 is formed thereon. The substrate 102 may be positioned on the bonding layer 670 while the bonding layer 670 is at a temperature above the melting point of the bonding layer 670, or while the bonding layer 670 is solid and then subsequently heated.

FIG. 6B illustrates a substrate 102 coupled to a puck 620 via a bonding layer 670 disposed therebetween. The puck 620 is positioned on an annular substrate support 673 located within an epitaxial growth chamber. Thus, the puck 620 performs a similar function as a substrate carrier, since the puck 620 supports the substrate 102 upon the annular substrate support 673 within the epitaxial growth chamber. In the embodiment shown in FIG. 6B, a substrate carrier is not required in addition to the puck 620, since the annular substrate support 673 allows light to contact the puck 620 from lamps disposed beneath the puck 620. The puck 620 is formed from silicon carbide having a high emissivity, and therefore, can absorb radiant energy and conduct the energy to the substrate 102 through the bonding layer 670.

Alternatively, the puck 620 may be used to support a plurality of substrates 102, similar to a solid substrate carrier. When supporting a plurality of substrates 102 on the puck 620, the puck 620 may include pockets having bottoms to support each of the substrates 102 therein. Desirably, a bonding layer 670 is positioned within each of the pockets to couple the substrates 102 to the portion of the puck 620 found within the pockets. Even though the substrates 102 may bow during processing, the bonding layer 670 (which will be fluid above the melting point of the material from which it is formed) will still remain in contact with the puck 620 and the substrate 102 due to the surface tension of the bonding layer 670 created between the puck 620 and the substrates 102. Thus, the thickness of the bonding layer 670 may not be uniform when the substrate bows during processing. Instead, the fluidity and surface tension of the bonding layer 670 will fill the space formed between the puck 620 and the substrates 102, therefore providing uniform thermal contact and heating of the substrate 102 during processing.

FIG. 6C illustrates a substrate 102 having an epitaxial layer 114 formed thereon being removed from the puck 620 after processing. Due to the adhesive forces created between the puck 620 and the substrate 102 due to the bonding layer 670, it can be difficult to separate the puck 620 from the substrate 102 by lifting the substrate 102 in a direction normal to the surface of the puck 620. The substrate 102 can more easily be removed from the puck 620 by sliding the substrate 102 parallel to the surface of the puck 620. The sliding action may be done manually or by an automated robotic device that is configured to cause the substrate 102 to be moved relative to the surface of the puck 620. Since the substrate 102 is removed while the bonding layer is in a liquid phase, portions of the bonding layer 670 may adhere to the lower surface of the substrate 102, and may need to be removed. Undesirably adhered portions of the bonding layer 670 can be removed using a wet etch process or a polishing process. Likewise, it may be necessary to occasionally remove and reapply a bonding layer 670 to the puck 620. The bonding layer 670 present on the puck 620 may also be removed using a wet etch process. After removal of the substrate 102 and optional cleaning of the puck 620, another substrate 102 may be processed using the bonding layer 670.

Benefits of the present invention include apparatus for allowing transparent substrates to absorb radiant heat by coupling a transferable puck thereto. The puck allows the substrate to be directly heated instead of indirectly heated via conduction through a substrate carrier. Additionally, the puck allows a substrate to be processed using a substrate carrier having an opening therethrough, which prevents the bottom surface of the substrate from contacting the substrate carrier when the substrate assumes a concave shape. The use the puck also provides for a more uniform temperature distribution during epitaxial growth processes compared to methods employing indirect heating.

Additionally, pucks can be reused on multiple substrates thereby reducing the costs which would otherwise be required to coat each substrate individually. Furthermore, the additional rigidity and support provided by the pucks allows a thinner substrate to be used for epitaxial growth process, which reduces production costs. Also, the extra support and rigidity reduces the occurrence of cracking or breaking of substrates, which increases production yield. The pucks also increase deposition uniformity in conventional substrate carriers having pockets or dished-shapes due to the high thermal conductance of the pucks. Even when the substrate bows and places the puck in contact with the substrate carrier pocket, the high thermal conductance of the puck allows the substrate to maintain a uniform temperature profile.

While the foregoing is directed to embodiments of the present invention, other and further embodiments of the invention may be devised without departing from the basic scope thereof, and the scope thereof is determined by the claims that follow.

We claim:

1. A transferable puck for supporting a substrate, comprising:
at least one electrode having a dielectric coating thereon, a portion of the at least one electrode exposed through the dielectric coating and adapted to be contacted by a biasing assembly.

2. The transferable puck of claim 1, wherein the at least one electrode is adapted to maintain a bias relative to a substrate disposed over the dielectric coating while being transferred independent of the biasing assembly.

3. The transferable puck of claim 1, wherein the puck is transferable between process chambers during a fabrication process.

4. The transferable puck of claim 2, wherein the at least one electrode comprises a metal having a thermal conductivity greater than about 120 W/m·K.

5. The transferable puck of claim 2, wherein the at least one electrode comprises titanium, tungsten, molybdenum, tantalum, cobalt or silicon carbide.

6. The transferable puck of claim 2, wherein the dielectric coating has an emissivity within a range from about 0.8 to about 0.95.

7. The transferable puck of claim 2, wherein the dielectric coating comprises alumina, aluminum nitride, silicon nitride, boron nitride, or pyrolytic boron nitride.

8. The transferable puck of claim 3, wherein the at least one electrode comprises tungsten, and the dielectric coating comprises alumina.

9. The transferable puck of claim 8, wherein the at least one electrode comprises two electrodes having semi-circular shapes of equal size, the semi-circular shapes having straight portions with a gap of constant width therebetween.

10. The transferable puck of claim 9, wherein the transferable puck is adapted to conform to the shape of the substrate during an epitaxial growth process.

11. A transferable puck for supporting a substrate, comprising:
at least one electrode; and
a dielectric coating disposed over the at least one electrode;
wherein a portion of the at least one electrode is exposed through the dielectric coating and adapted to be contacted by a biasing assembly, the at least one electrode adapted to maintain a bias relative to the substrate supported on the transferable puck while being transferred independent of the biasing assembly during a fabrication process.

12. The transferable puck of claim 11, wherein the at least one electrode comprises titanium, tungsten, molybdenum, tantalum, cobalt or silicon carbide.

13. The transferable puck of claim 12, wherein the dielectric coating comprises alumina, aluminum nitride, silicon nitride, boron nitride, or pyrolytic boron nitride.

14. The transferable puck of claim 11, wherein the at least one electrode includes a circular-shaped disk having vertical extensions extending therefrom.

15. The transferable puck of claim 11, wherein the at least one electrode has a thickness between about 100 micrometers and about 1 millimeter, and the dielectric coating has a thickness between about 100 nanometers and about 1000 nanometers.

16. A method of forming an epitaxial film, comprising:
disposing a light-absorbing material on a first surface of an optically transparent substrate;
positioning the optically transparent substrate within a processing chamber;
delivering energy to the light-absorbing material from one or more lamps, wherein the optically transparent substrate is supported by a substrate support disposed in the processing chamber, and the one or more lamps are positioned to deliver energy to the light-absorbing material through an opening formed in the substrate support; and
forming an epitaxial layer on a second surface of the optically transparent substrate that is opposite to the first surface of the optically transparent substrate.

17. The method of claim 16, wherein the light-absorbing material has an emissivity within a range from about 0.3 to about 0.95.

18. The method of claim 16, wherein disposing the light-absorbing material on the first surface further comprises bonding the light-absorbing material to the optically transparent substrate using a bonding material having a melting point less than about 130 degrees Celsius.

19. The method of claim 16, wherein disposing the light-absorbing material on the first surface further comprises depositing a light-absorbing material on the first surface of the optically transparent substrate.

20. The method of claim 16, wherein disposing the light-absorbing material on the first surface further comprises electrostatically chucking the light-absorbing material to the first surface of the optically-transparent substrate.

21. The method of claim 16, further comprising positioning a quartz catch pan beneath the substrate support within the processing chamber to collect particulate matter thereon.

22. A substrate used to support at least a portion of a light emitting diode or laser diode device during processing, comprising:
an optically transparent substrate having a first side and a second side, wherein the second side is on a side opposite to the first side; and
a light-absorbing material disposed on the first side of the optically transparent substrate, and the second side is configured to receive one or more layers used to form a light emitting diode or laser diode device.

23. The substrate of claim 22, wherein the optically transparent substrate has an optical transmittance of at least 80% for wavelengths of light between about 0.3 and about 4.5 μm.

24. The substrate of claim 22, wherein the optically transparent substrate comprises sapphire or silicon.

25. The substrate of claim 22, wherein the second side has a plurality of surface features formed thereon.

26. The substrate of claim 22, wherein the light-absorbing material comprises polysilicon carbide, titanium, titanium nitride, tungsten, tungsten nitride, cobalt, boron nitride or silicon nitride.

27. The substrate of claim 26, wherein the light-absorbing material has a thickness between about 0.1 micrometers to about 300 micrometers.
